(19) United States
(12) Patent Application Publication
(10) Pub. No.: US 2009/0130467 A1
(43) Pub. Date: May 21, 2009

(54) TRANSFER COMPONENT AND LASER-ASSISTED TRANSFER SYSTEM USING THE SAME

(75) Inventors: SUNG-HO LIU, Kaohsiung City (TW); CHUN-HAO TSENG, Pingtung County (TW); CHUN-MING CHEN, Hualien County (TW); TZONG-MING WU, Taipei City (TW)

Correspondence Address: WPAT, PC, 7225 BEVERLY ST., ANNANDALE, VA, 22003, US

(73) Assignee: INDUSTRIAL TECHNOLOGY RESEARCH INSTITUTE, Hsin-Chu (TW)

(21) Appl. No.: 12/251,868

(22) Filed: Oct. 15, 2008

(30) Foreign Application Priority Data
Nov. 21, 2007 (TW) 096144023

(51) Int. Cl. B32B 15/04; B05D 1/32

(52) U.S. Cl. 428/457; 118/624

(57) ABSTRACT

A transfer component and a laser-assisted transfer system using the same are provided. The laser-assisted transfer system comprises: a multimode laser source; a beam transformer; a scanner module; and a transfer component. The beam transformer is capable of transforming a multimode laser beam generated from the multimode laser source into a rectangular beam and then feeding the rectangular beam into the scanner module to form a large-area scanning laser beam. The transfer component comprises a conductive thin film and an insulating thin film. The conductive thin film receives a scanning laser beam from the scanner module and is ablated while the ablation of the conductive thin film is transferred onto the insulating thin film. In an exemplary embodiment, the transfer component comprising a metal thin film and an organic thin film is used for enabling the system to perform large-area pattern transfer with high efficiency.

### BACKGROUND OF THE INVENTION

1. Field of the Invention

The present invention generally relates to a laser-assisted transfer system and, more particularly, to a laser-assisted transfer system capable of transferring a large-area pattern on an organic substrate to enhance the pattern transfer performance.

2. Description of the Prior Art

Laser assisted pattern transfer technology has been widely used in many industries. However, there are some issues such as:

1. The repetition rate of the excimer laser is too low (lower than 300 Hz);

2. The Nd-Yag laser beam is Gaussian distributed, which results in a small transfer area;

3. The UV laser destroys organic thin films;

4. The moving speed is lower than 0.2 m/s when a platform is shifted to change the transfer position;

5. The scanned area for the single-point transfer technique is 0.25×0.25 cm², which results in low speed and is not suitable for large-area pattern transfer.

In U.S. Pat. No. 4,970,196 “Method and apparatus for the thin film deposition of materials with a high power pulsed laser”, a laser assisted pattern transfer technique for metal materials (such as copper, silver, aluminum, platinum and chromium) or non-metal materials (such as ceramic) is disclosed. In U.S. Pat. No. 5,173,441 “Laser ablation deposition process for semiconductor manufacture”, a laser assisted pattern transfer technique for metal materials is disclosed for semiconductor processing. In both of these two patents, the excimer laser is used to perform pattern transfer in a vacuum chamber or a chamber with specific gas. These two patents have problems as stated above.

Concerning organic light emitting diode (OLED) processing, patterned metal layers are required to be formed on organic thin films. Since organic thin films are not resistant to chemical solutions, dry processing is used such as thermal evaporation, inkjet printing, and laser assisted transfer. However, there are still problems such as unavailability in large-area transfer, poor precision, and difficulty in preparation of transfer thin films. Even though laser assisted transfer results in high precision, the organic thin film is easily destroyed by laser beams.

### SUMMARY OF THE INVENTION

It is an object of the present invention to provide to a laser-assisted transfer system capable of transferring a large-area pattern on an organic substrate to enhance the pattern transfer performance.

In order to achieve the foregoing object, the present invention provides a laser-assisted transfer system, comprising: a laser source, capable of generating a multimode laser beam; a beam transformer, capable of transforming the multimode laser beam into a rectangular beam; a scanner module, capable of scanning the rectangular beam to form a scanning laser beam; and a transfer component, capable of receiving the scanning laser beam to generate a transfer pattern.

In order to achieve the foregoing object, the present invention further provides a transfer component, comprising: a metal thin film, capable of receiving a laser beam to partially ablate the metal thin film; and an organic thin film, being disposed under the metal thin film to receive the partially ablated metal thin film and form a transfer pattern.

### BRIEF DESCRIPTION OF THE DRAWINGS

The objects, spirits and advantages of the preferred embodiments of the present invention will be readily understood by the accompanying drawings and detailed descriptions, wherein:

FIG. 1 is a schematic diagram of a laser-assisted transfer system according to one embodiment of the present invention;

FIG. 2 is a partially enlarged diagram showing a transfer component in the laser-assisted transfer system in FIG. 1;

FIG. 3 is a schematic diagram of a laser-assisted transfer system according to another embodiment of the present invention;

FIG. 4 shows a silver pattern transferred onto an organic thin film by infrared (IR) multimode laser assisted transfer;

FIG. 5 is a partially enlarged diagram of FIG. 4;

FIG. 6 shows a silver pattern transferred onto an organic thin film by infrared (IR) excimer laser assisted transfer; and

FIG. 7 is a partially enlarged diagram of FIG. 6.

### DETAILED DESCRIPTION OF THE PREFERRED EMBODIMENT

The present invention can be exemplified but not limited by the preferred embodiments as described hereinafter.

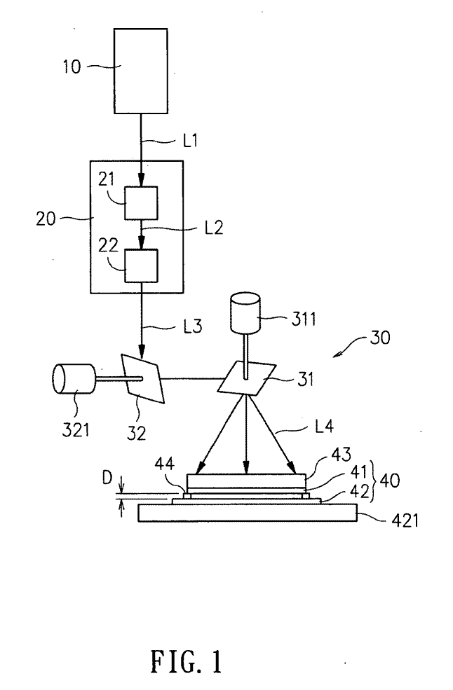

Please refer to FIG. 1, which is a schematic diagram of a laser-assisted transfer system according to one embodiment of the present invention. The laser-assisted transfer system comprises a laser source 10, a beam transformer 20, a scanner module 30 and a transfer component 40.

The laser source 10 is capable of generating a multimode laser beam L1. The wavelength of the multimode laser beam L1 is at least 400 nm. The beam transformer 20 comprises a beam homogenizer 21 and a beam shaper 22. Preferably, the beam homogenizer 21 and the beam shaper 22 can be integrated as a module. The beam homogenizer 21 is capable of flat-topping the multimode laser beam L1. The beam shaper 22 is capable of shaping the flat-topped multimode laser beam L2 into a rectangular beam L3. The beam shaper 22 is capable of adjusting the size of the rectangular beam.

Moreover, the scanner module 30 scans the rectangular beam L3 to form a scanning laser beam L4 with a large cross-sectional area. The scanner module 30 comprises an X-axis oscillating mirror 31 and a Y-axis oscillating mirror 32, which are perpendicular. The X-axis oscillating mirror 31 and the Y-axis oscillating mirror 32 are driven by motors 311 and 321, respectively, to oscillate and scan horizontally and vertically. After the Y-axis oscillating mirror 32 receives the rectangular beam L3, the rectangular beam L3 is reflected to the X-axis oscillating mirror 31, which generates the scanning laser beam L4 with a large cross-sectional area to be incident on the transfer component 40. The scanner module 30 is programmable so as to programmably control the multimode laser beam. Moreover, the scanner module 30 can be installed on a positioning platform (not shown) to perform focus compensation during scanning.

The transfer component 40 comprises a conductive thin film 41 and an insulating thin film 42. The conductive thin film 41 is supported and positioned by a platform 43. The insulating thin film 42 is disposed on a carrier 421. In the present embodiment, a stainless steel washer 44 is disposed between the conductive thin film 41 and the insulating thin film 42 to form a gap D to separate the conductive thin film 41 and the insulating thin film 42. The gap D is between 5 μm to 100 μm. Experimentally, the wider the gap, the larger the transfer area. Alternatively, it is feasible that the conductive thin film 41 and the insulating thin film 42 contact each other without disposing a washer to form a gap therebetween. In other words, the conductive thin film 41 and insulating thin film 42 can be implemented according to practical use.

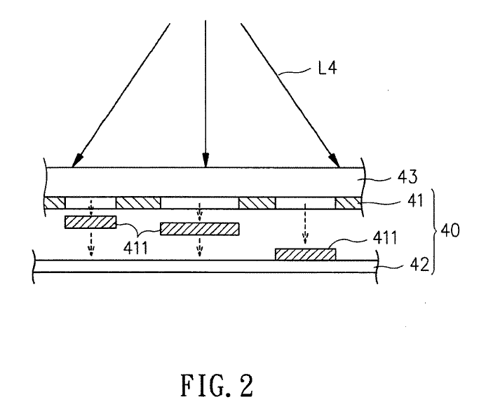

Please refer to FIG. 2, which is a partially enlarged diagram showing a transfer component in the laser-assisted transfer system in FIG. 1. The conductive thin film 41 receives the large-area scanning laser beam L4 scanned by the scanner module 30 (as shown in FIG. 1) so that the conductive thin film 41 absorbs laser energy to partially ablate the conductive thin film 41. The partially ablated conductive thin film is received by the insulating thin film 42 disposed under the metal thin film to form a transfer pattern.

It is noted that, referring to FIG. 1, in the laser-assisted transfer system of the present invention, the conductive thin film 41 can be implemented by using any conductive material such as gold (Au), silver (Ag) and an alloy and the insulating thin film 42 can be implemented by using any insulating material such as ceramic, pentacene and any other organic material. Since the laser source 10 of the present invention is capable of generating a multimode laser beam, the laser source 10 is suitable for use with not only a general transfer component but also for pattern transfer from a metal thin film onto an organic thin film. In other words, when the conductive thin film 41 is a metal thin film and the insulating thin film 42 is an organic thin film, the metal thin film is highly absorbent to the multimode laser beam and tends to being ablated, while the organic thin film is lowly absorbent to the multimode laser beam and is nearly unaffected by the multimode laser beam. Therefore, it is easy to perform pattern transfer from the metal thin film onto the organic thin film. Accordingly, the laser-assisted transfer system of the present invention is suitable for use in OLED processing to transfer the pattern on a metal thin film onto an organic thin film to enhance the manufacturing throughput and yield because of availability in large-area pattern transfer and harmlessness to the organic thin film.

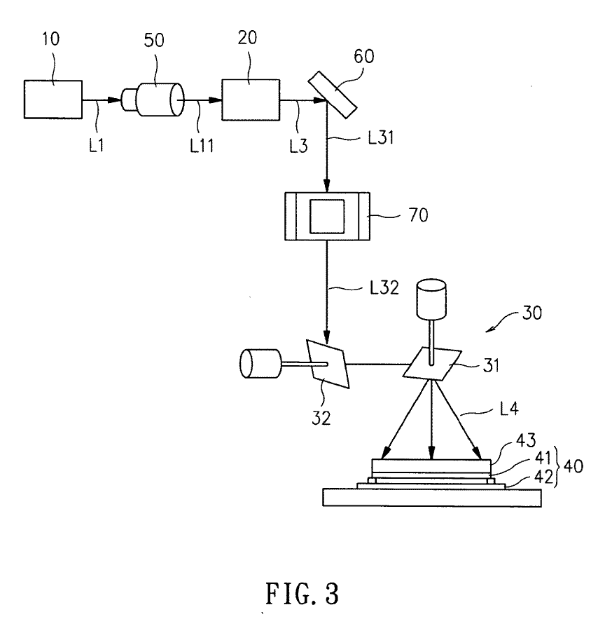

Please refer to FIG. 3, which is a schematic diagram of a laser-assisted transfer system according to another embodiment of the present invention. The present embodiment is based on FIG. 1 and, similarly, comprises a laser source 10, a beam transformer 20, a scanner module 30 and a transfer component 40. The functions and objectives thereof are not repeated here. The present embodiment is characterized in that a beam expander 50 is disposed between the laser source 10 and the beam transformer 20 to expand the multimode laser beam L generated by the laser source 10 to a larger laser beam L11 to enter the beam transformer 20. It is noted that the beam expander 50 is implemented by using at least an optical module capable of adjusting the size of a light beam. The present embodiment is only exemplified by using a beam expander. Moreover, a reflector 60 and a mask 70 are disposed between the beam transformer 20 and the scanner module 30. The reflector 60 is capable of receiving a rectangular beam L3 generated by the beam transformer 20 and changing the traveling orientation of the rectangular beam L3. That is, the reflector 60 is capable of reflecting the horizontal multimode laser beam L1 generated by the laser source 10 to a vertical rectangular beam L31, which is to be patterned by the mask 70 as a patterned laser beam L32. The patterned laser beam L32 is scanned by the X-axis oscillating mirror 31 and the Y-axis oscillating mirror 32 to form a large-area scanning laser beam L4. The large-area scanning laser beam L4 is then received by the conductive thin film 41 in the transfer component 40 to transfer on the insulating thin film 42.

Accordingly, the transfer component and the laser-assisted transfer system using the same disclosed in the present invention can be used to achieve large-area pattern transfer and enhance the performance. The disclosure of the present invention is suitable for use in pattern transfer onto an organic thin film when a multimode laser beam is used.

Therefore, the present invention has advantages over the prior art references such as:

1. From a view of speed, the repetition rate of the conventional excimer laser is lower than 300 Hz. It requires a platform to change the transfer position with a slow moving speed lower than 0.2 m/s. In the present invention, a multimode laser is used with a repetition rate of 3˜50 KHz and the scanning speed of the scanner is 1.0 m/s. In other words, the repetition rate of the present invention is at least 10 times the repetition rate of the prior art and the scanning speed is at least 5 times the scanning speed of the prior art.

2. From a view of area, the scanned area for the single-point transfer technique is smaller than 0.25×0.25 cm², while the scanned area of the present invention is 5×5 cm², which is 400 times the scanned area of the prior art.

3. From a view of precision, the pattern transfer is not available onto an organic thin film while the scanner module of the present invention exhibits a precision of 10 μm when a mask is used.

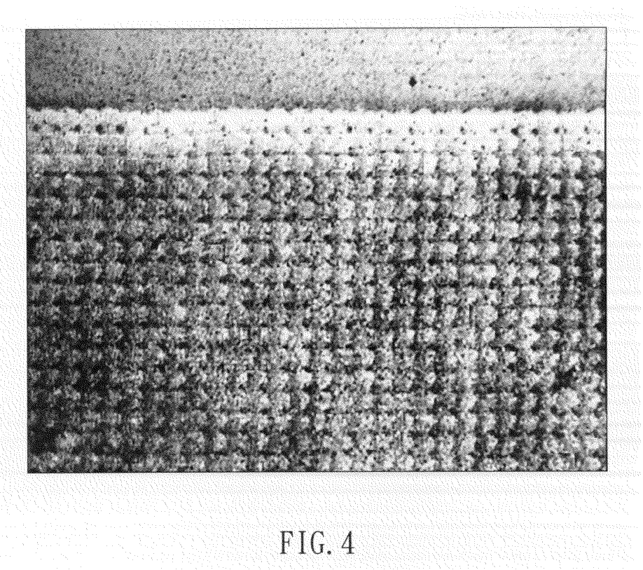

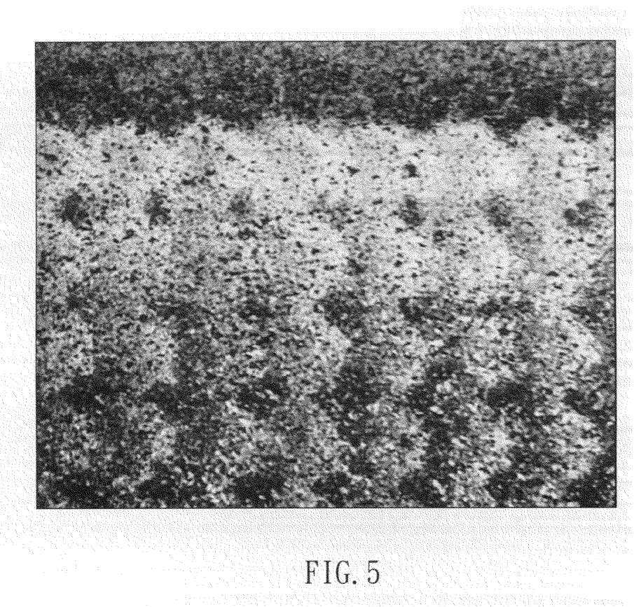

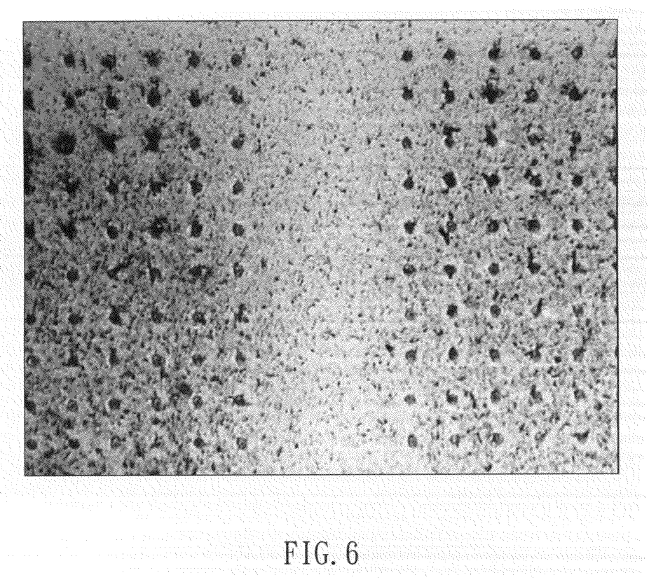

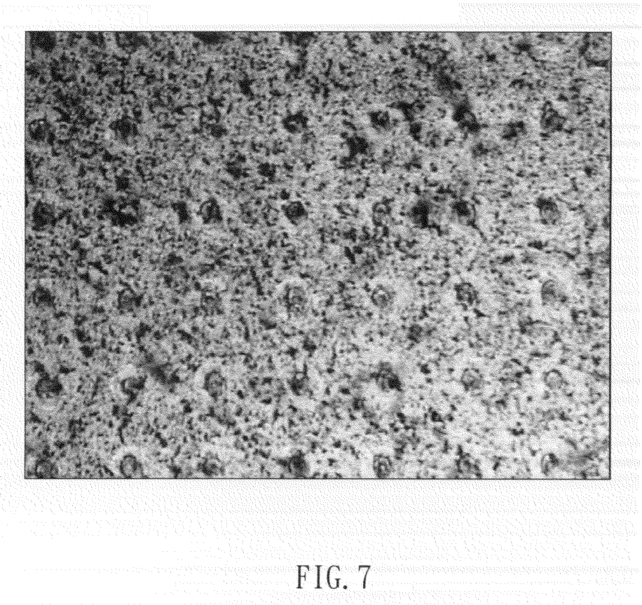

Moreover, FIG. 4 to FIG. 7 show a silver pattern transferred from a metal film onto an organic thin film by laser assisted transfer. In FIG. 4 and FIG. 5, 1064-nm infrared (IR) multimode laser assisted transfer is used to transfer a silver (Ag) pattern onto an organic thin film. It is shown that a thin film is deposited without destroying the organic thin film. On the contrary, in FIG. 6 and FIG. 7, 355-nm UV laser assisted transfer is used to transfer a silver (Ag) pattern onto an organic thin film. It is shown that the organic thin film is damaged by the laser to form many burnt pin holes.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. A laser-assisted transfer system, comprising:
a laser source, capable of generating a multimode laser beam;
a beam transformer, capable of transforming the multimode laser beam into a rectangular beam;
a scanner module, capable of scanning the rectangular beam to form a scanning laser beam; and
a transfer component, capable of receiving the scanning laser beam to generate a transfer pattern.

2. The laser-assisted transfer system as recited in claim 1, wherein a mask is disposed between the beam transformer and the scanner module for pattern transfer.

3. The laser-assisted transfer system as recited in claim 1, wherein a reflector is disposed between the beam transformer and the mask to reflect the multimode laser beam.

4. The laser-assisted transfer system as recited in claim 1, wherein the beam transformer comprises:
a beam homogenizer, capable of flat-topping the multimode laser beam; and
a beam shaper, capable of shaping the flat-topped multimode laser beam into the rectangular beam.

5. The laser-assisted transfer system as recited in claim 4, wherein the beam shaper is capable of adjusting the size of the rectangular beam.

6. The laser-assisted transfer system as recited in claim 1, wherein at least an optical module capable of adjusting the size of the multimode laser beam is disposed between the laser source and the beam transformer to magnify the size of the multimode laser beam before it enters the beam transformer.

7. The laser-assisted transfer system as recited in claim 1, wherein the scanner module is programmable.

8. The laser-assisted transfer system as recited in claim 1, wherein the scanner module is disposed on a positioning platform to perform focus compensation during scanning.

9. The laser-assisted transfer system as recited in claim 1, wherein the transfer component comprises:
a conductive thin film, capable of receiving the scanning laser beam to partially ablate the conductive thin film; and
an insulating thin film, being disposed under the conductive thin film to receive the partially ablated conductive thin film and form a transfer pattern.

10. The laser-assisted transfer system as recited in claim 9, wherein the conductive thin film is a metal thin film and the insulating thin film is an organic thin film.

11. The laser-assisted transfer system as recited in claim 1, wherein the conductive thin film and the insulating thin film are separated.

12. The laser-assisted transfer system as recited in claim 1, wherein the conductive thin film and the insulating thin film contact each other.

13. A laser-assisted transfer system, comprising:
a laser source, capable of generating a multimode laser beam;
a beam transformer, capable of transforming the multimode laser beam into a rectangular beam;
a scanner module, capable of scanning the rectangular beam to form a scanning laser beam; and
a transfer component, comprising:
a metal thin film, capable of receiving the scanning laser beam to partially ablate the metal thin film; and
an organic thin film, being disposed under the metal thin film to receive the partially ablated metal thin film and form a transfer pattern.

14. The laser-assisted transfer system as recited in claim 13, wherein a mask is disposed between the beam transformer and the scanner module for pattern transfer.

15. The laser-assisted transfer system as recited in claim 13, wherein a reflector is disposed between the beam transformer and the mask to reflect the multimode laser beam.

16. The laser-assisted transfer system as recited in claim 13, wherein the beam transformer comprises:
a beam homogenizer, capable of flat-topping the multimode laser beam; and
a beam shaper, capable of shaping the flat-topped multimode laser beam into the rectangular beam.

17. The laser-assisted transfer system as recited in claim 16, wherein the beam shaper is capable of adjusting the size of the rectangular beam.

18. The laser-assisted transfer system as recited in claim 13, wherein at least an optical module capable of adjusting the size of the multimode laser beam is disposed between the laser source and the beam transformer to magnify the size of the multimode laser beam before it enters the beam transformer.

19. The laser-assisted transfer system as recited in claim 13, wherein the scanner module is programmable.

20. The laser-assisted transfer system as recited in claim 13, wherein the scanner module is disposed on a positioning platform to perform focus compensation during scanning.

21. The laser-assisted transfer system as recited in claim 13, wherein the metal thin film and the organic thin film are separated.

22. The laser-assisted transfer system as recited in claim 13, wherein the metal thin film and the organic thin film contact each other.

23. A transfer component, comprising:
a metal thin film, capable of receiving a laser beam to partially ablate the metal thin film; and
an organic thin film, being disposed under the metal thin film to receive the partially ablated metal thin film and form a transfer pattern.

24. The laser-assisted transfer system as recited in claim 23, wherein the metal thin film and the organic thin film are separated.

25. The laser-assisted transfer system as recited in claim 23, wherein the metal thin film and the organic thin film contact each other.
